(19) United States
(12) Patent Application Publication
(10) Pub. No.: US 2020/0012356 A1
(43) Pub. Date: Jan. 9, 2020

(54) SWITCH SYSTEM

(71) Applicant: FUJITSU COMPONENT LIMITED, Tokyo (JP)

(72) Inventor: Masaki HORIKAWA, Tokyo (JP)

(73) Assignee: FUJITSU COMPONENT LIMITED, Tokyo (JP)

(21) Appl. No.: 16/440,231

(22) Filed: Jun. 13, 2019

(30) Foreign Application Priority Data
Jul. 4, 2018 (JP) 2018-127509

(51) Int. Cl. G06F 3/0362; H03K 17/96; G06F 3/041

(52) U.S. Cl. CPC G06F 3/0362; G06F 3/041; H03K 17/9631

(57) ABSTRACT

A switch system includes: a projection; a plurality of switches that are arranged on a side surface of the projection along a circumferential direction, each switch detecting touch to the side surface of the projection by an operator as on or off; and a determiner that acquires on/off states of the switches, and determines a rotational direction of an operator's finger along the circumferential direction of the projection based on a current on/off state currently acquired from each switch and a previous on/off state previously acquired from each switch.

### CROSS-REFERENCE TO RELATED APPLICATION

This application is based upon and claims the benefit of priority of the prior Japanese Patent Application No. 2018-127509 filed on Jul. 4, 2018, the entire contents of which are incorporated herein by reference.

### FIELD

A certain aspect of the embodiments is related to a switch system.

### BACKGROUND

There is known an input device for inputting information by an operator rotating a cylinder-shaped operation unit (e.g. Document D1: International Publication Pamphlet No. 2016/152732).

### SUMMARY

According to a first aspect of the present disclosure, there is provided a switch system including: a projection; a plurality of switches that are arranged on a side surface of the projection along a circumferential direction, each switch detecting touch to the side surface of the projection by an operator as on or off; and a determiner that acquires on/off states of the switches, and determines a rotational direction of an operator's finger along the circumferential direction of the projection based on a current on/off state currently acquired from each switch and a previous on/off state previously acquired from each switch.

According to a second aspect of the present disclosure, there is provided a switch system including: a projection; a plurality of switches that are arranged on a side surface of the projection along a circumferential direction, each switch detecting touch to the side surface of the projection by an operator as on or off; and a determiner that determines whether an on/off state of each of the switches is not changed for a given time period, and determines a rotational direction of an operator's finger along the circumferential direction of the projection based on on/off states of the switches when it is determined that the on/off state of each of the switches is not changed for the given time period.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A and 1B are cross-sectional views of an operation unit;

FIG. 2 is a perspective view of a switch system;

FIG. 3 is a block view of the switch system;

FIG. 4 is a flowchart illustrating a determination processing of a grip way by a determination unit;

FIG. 5 is a flowchart illustrating a determination processing of a rotational direction by the determination unit; and

FIGS. 6A to 6C are views illustrating an example of the determination of the rotational direction.

### DESCRIPTION OF EMBODIMENTS

A device using an electrostatic switch is known as an information input device. Such an information input device often has a planar operation surface. Since the operation surface is planar, it is difficult to give the same operability as a switch which operates by rotation. In an example of the above Document D1, since an operation unit to be physically rotated is required, a mechanism of the information input device is complicated.

The present embodiment provides a switch system capable of performing input of rotating operation.

Hereinafter, a description will now be given of embodiments according to the present invention with reference to drawings.

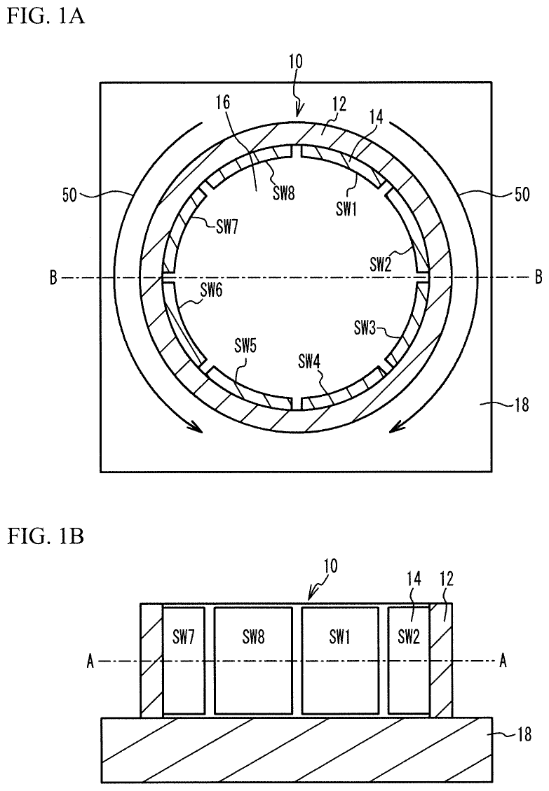

(First Embodiment) FIGS. 1A and 1B are cross-sectional views of an operation unit 10 according to a first embodiment. FIG. 1A is a cross-sectional view taken along a line A-A in FIG. 1B. FIG. 1B is a cross-sectional view taken along a line B-B in FIG. 1A. A projection 12 to be operated by an operator is fixed on a substrate 18, as illustrated in FIGS. 1A and 1B. The projection 12 is a hollow column (e.g. a cylinder) in which a cavity 16 is formed. In an example of FIGS. 1A and 1B, a side surface of the projection 12 is perpendicular to an upper surface of the substrate 18. The side surface of the projection 12 may be inclined to the upper surface of the substrate 18.

A plurality of switches 14 are arranged on an inner side surface of the projection 12 along a circumferential direction. Hereinafter, a description will be given of an example in which eight switches 14 of SWs 1 to 8 are provided, but it is sufficient that the plurality of switches 14 are provided. In order to improve an accuracy of the detection of rotational operation, the number of switches 14 is preferably large. When the operator operates the operation unit 10, the operator grips the projection 12 with fingers so that the fingers touch an outer surface of the projection 12. Some switches 14 corresponding to positions where the operator's fingers touch are turned on, and the other switches 14 corresponding to positions where the operator's fingers do not touch are turned off. Conversely, some switches 14 which the operator's fingers touch may be turned off, and the other switches 14 which the operator's fingers do not touch may be turned on. The switches 14 detect the presence or absence of touch to the surface of the projection 12 by the operator's fingers, as on or off, respectively.

When the projection 12 is used as a rotary input switch, the operator rotates grip clockwise or counterclockwise as indicated by arrows 50 while gripping the projection 12. At this time, the projection 12 is fixed to the substrate 18, and therefore the operator's fingers move so as to slide against the side surface of the projection 12. With the movement of the fingers, the switches 14 which the fingers touch are turned on, and the other switches 14 which the fingers do not touch are turned off. The switches 14 of an ON state and an OFF state are appropriately changed.

Each switch 14 is, for example, a capacitance switch. For this reason, even if the operator's fingers do not directly touch the switches 14, the switches 14 can detect the touch to the projection 12 by the operator's fingers. The diameter of the projection 12 is 1 cm to 10 cm, for example, and can be appropriately set in a range that can be gripped by the operator. The thickness of the projection 12, i.e., a height from the substrate is 1 mm to 10 mm, for example, and can be appropriately set in a range where each switch 14 operates. The projection 12 may be the insulator such as a resin or other material such as a piece of wood. Each switch 14 may be provided on the outer surface of the projection 12. The switch 14 may be other type of switch such as a mechanical switch or a membrane switch. When the switch 14 is the mechanical switch or membrane switch, it is preferable that the switch 14 is provided on the outer surface of the projection 12.

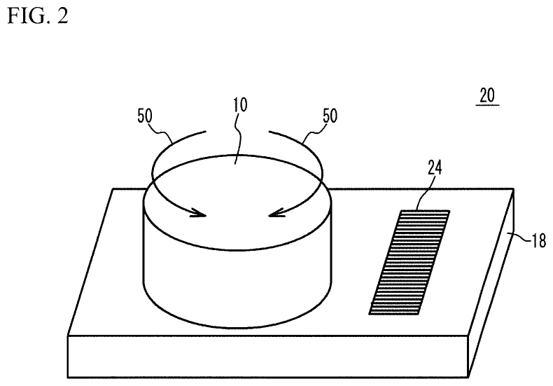

FIG. 2 is a perspective view of a switch system according to the first embodiment. The operation unit 10 and an indicator 24 are provided on the substrate 18, as illustrated in FIG. 2. The operator grips the operation unit 10, and moves the fingers gripping the operation unit 10 so as to rotate the fingers as indicated by one of the arrows 50. The indicator 24 indicates a rotational direction of the operation of the operation unit 10 to ensure visibility of the operation direction and an operation amount of the operation unit 10. For example, the indicator 24 is a LED (Light Emitting Diode). Here, the shape of the indicator 24 is not limited to an illustrated embodiment, and the indicator 24 may be provided in an arc shape around the projection 12.

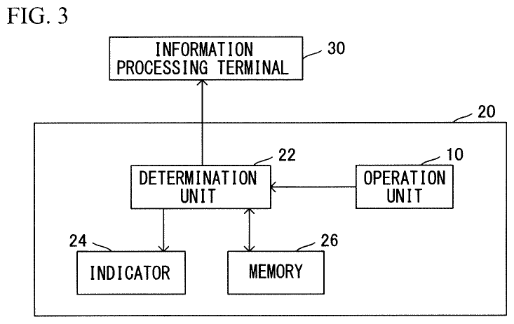

FIG. 3 is a block view of the switch system. A switch system 20 includes the operation unit 10, a determination unit 22, the indicator 24 and a memory 26. The determination unit 22 is connected to an information processing terminal 30 via an external interface. The interface is a wired system or wireless system such as a Universal Serial Bus (USB) system, an Inter-Integrated Circuit (I2C) system, or a Universal Asynchronous Receiver/Transmitter (UART) system.

The determination unit 22 is a processor such as a microcomputer or Central Processing Unit (CPU), for example. The determination unit 22 determines a direction in which the operator rotates the grip based on ON and OFF state (switch state) of each of the switches 14. The determination unit 22 causes the indicator 24 to indicate a determination result. Moreover, the determination unit 22 outputs the determination result to the information processing terminal 30. The memory 26 stores information such as the switch states of the switches 14, and a flag indicating that the grip way is determined (grip flag).

When the operation unit 10 is used as a rotational switch, the operator inputs information by tracing a side surface of the operation unit 10 so as to rotate the side surface while gripping the operation unit 10h with the fingers. However, since the operation unit 10 is fixed to the substrate 18, the rotational direction of the grip is sometimes determined erroneously. For example, the grip way of the operation unit 10 differs from one person to another, and therefore can affect the determination of the rotational direction. For this reason, it is more difficult to determine an operation direction of switches disposed on the surface of the cylindrical projection as an operator intends, comparing to the case of determining an operation direction of the switches formed on a planar surface. This embodiment realizes the determination of the operation direction more reliably and more stably.

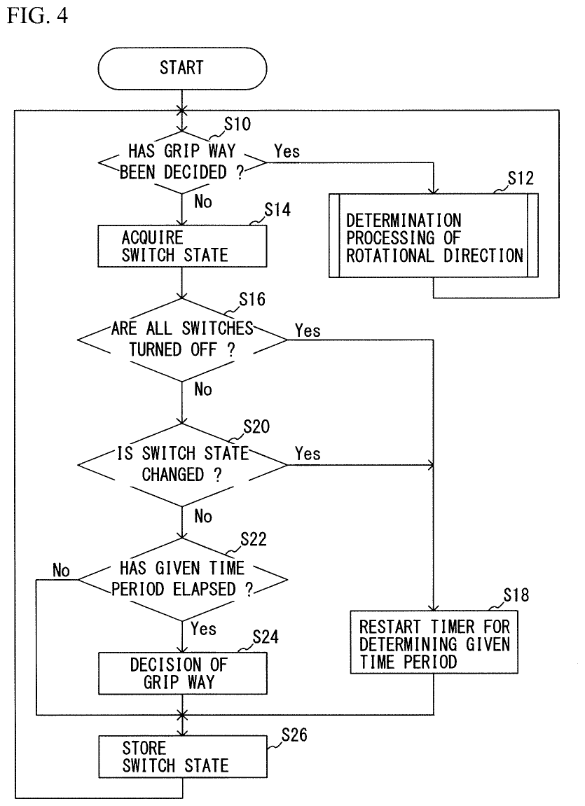

FIG. 4 is a flowchart illustrating a determination processing of the grip way of the projection 12 to be executed by the determination unit 22. The processing of FIG. 4 is to determine whether the operator touches the projection 12 with the intention of operating the projection 12 or not by determining whether the grip way has been decided. As illustrated in FIG. 4, the determination unit 22 determines whether the grip way of the projection 12 by the operator has been decided (S10). For example, when the grip flag is set in the memory 26, the determination unit 22 determines that the determination result is YES. When the grip flag is not set in the memory 26, the determination unit 22 determines that the determination result is NO. When the determination result of S10 is YES, the determination unit 22 executes a determination processing of a rotational direction (S12). Then, the procedure returns to S10.

When the determination result of S10 is NO, the determination unit 22 acquires the switch state from each of the switches 14 (S14). The determination unit 22 determines whether all of the switches 14 are turned off based on the switch state acquired in S14 (S16). When the determination result of S16 is YES, the determination unit 22 starts measuring the time by restarting a timer for determining a given time period (S18). Then, the procedure advances to S26.

When the determination result of S16 is NO, i.e., at least one switch 14 is turned on, the determination unit 22 determines whether the switch state acquired in S14 is changed from the previous switch state stored in the memory 26 in S26 or S56 described later (S20). When the determination result of S20 is YES, it is thought that the grip way has changed before the given time period measured by the timer elapses, and therefore the procedure advances to S18.

When the switch state is not changed in S20 (NO), the determination unit 22 determines whether the given time period has elapsed after the timer is restarted in S18 (S22). When the determination result of S22 is YES, this means that the grip way has not changed for the given time period or more. Therefore, the determination unit 22 determines that the grip way has decided (S24), and sets the grip flag in the memory 26 for example. Then, the procedure proceeds to S26.

When the determination result of S22 is NO, the determination unit 22 determines that the grip way has not decided, and the procedure proceeds to S26.

The determination unit 22 stores the switch state acquired in S14 into the memory 26 as a previous switch state (S26). Then, the procedure returns to S10.

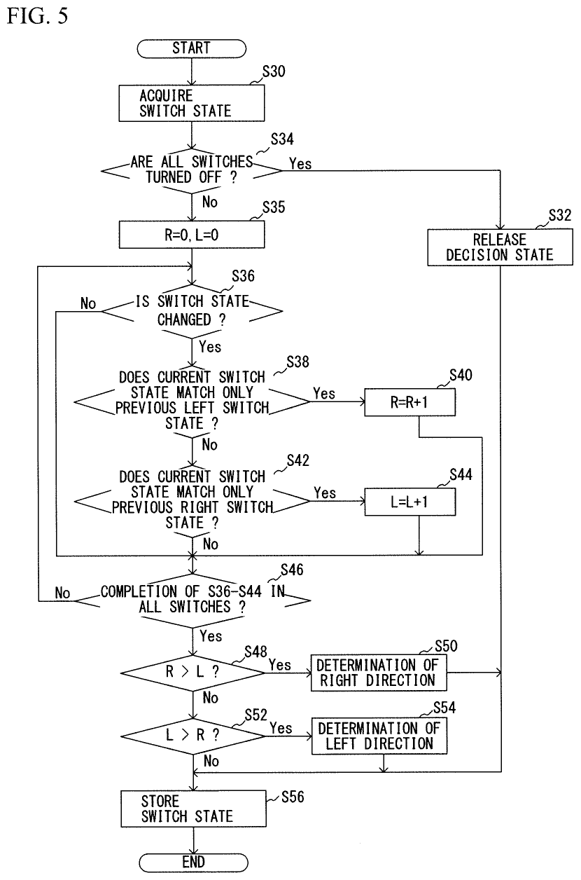

In FIG. 4, when the switch states of all the switches 14 do not change for the given time period or more, the determination unit 22 determines that the grip way of the projection 12 by the operator has decided. The given time period is 100 msec to 1 sec, for example, preferably 10 msec to 1 sec. In this case, it is considered that the operator has gripped the projection 12 with the intention of operating the projection 12, and the processing of FIG. 5 is performed.

FIG. 5 is a flowchart illustrating a determination process of a rotational direction of the grip to be executed by the determination unit 22. FIG. 5 is the flowchart corresponding to the process of S12. When it is determined that the grip way has decided in FIG. 4 and the operator grips the projection 12, the process of FIG. 5 is performed.

As illustrated in FIG. 5, the determination unit 22 acquires the switch state at that time from each of the switches 14 (S30). The determination unit 22 determines whether all of the switches 14 are turned off based on the acquired switch state (S34). When all of the switches 14 are turned off, i.e., the determination result of S34 is YES, it is considered that the operator has released the fingers from the projection 12. Therefore, the determination unit 22 releases a grip way decision state (S32), and clears the grip flag in the memory 26, for example. Then, the procedure advances to S56, and the determination unit 22 stores the switch state at that time. Then, the processing according to FIG. 4 is performed. In this case, the determination unit 22 determines that the determination result of S10 is NO, and the processing of the decision of the grip way of S14 and the subsequent steps is performed again.

On the other hand, when any one of the switches 14 is turned on, i.e., the determination result of S34 is NO, the determination unit 22 clears a right counter R and a left counter L (S35). The right counter R is a counter for counting the number of times the finger is determined to have moved in the right direction between the adjacent switches 14. The left counter L is a counter for counting the number of times the finger is determined to have moved in the left direction between the adjacent switches 14. The determination of a moving direction is described later. The determination unit 22 executes the process of S36 to S44 for each of the switches 14. First, the determination unit 22 determines whether the switch state acquired in S30 is changed from the previous switch state stored in the memory 26 with respect to each target switch to be processed (S36). When the switch state is not changed, i.e., the determination result of S36 is NO, the determination unit 22 determines that the operator's finger is not moving in each target switch, and does not execute the process of S38 to S44 and advances to S46.

On the other hand, when the switch state of the target switch 14 is changed, i.e., the determination result of S36 is YES, the determination unit 22 compares the current switch state acquired in S30 with respect to the target switch with previous switch states stored in the memory 26 with respect to two switches arranged on both sides of the target switch. As a result of the comparison, the determination unit 22 determines whether the current switch state of the target switch matches only the previous switch state of the switch on the left side (S38). When the determination result of S38 is YES, the current switch state of the target switch matches the previous switch state of the switch on the left side, and does not matches the previous switch state of the switch on the right side. At this time, the determination unit 22 determines that the finger has moved in the right direction from the previous switch state to the current switch state, and increments the right counter R (S40). Then, the procedure advances to S46.

When the determination result of S38 is NO, the current switch state of the target switch is any one of (i) matching the previous switch states of the respective switches on both sides, (ii) not matching the previous switch states of the respective switches on both sides, or (iii) matching the previous switch state of the switch on the right side and not matching the previous switch state of the switch on the left side. Therefore, the determination unit 22 determines whether the current switch state of the target switch matches only the previous switch state of the switch on the right side (S42). When the determination result of S42 is YES, the current switch state of the target switch only matches the previous switch state of the switch on the right side. At this time, the determination unit 22 determines that the finger has moved in the left direction from the previous switch state to the current switch state, and increments the left counter L (S44). Then, the procedure advances to S46.

When the determination result of S42 is NO, the determination unit 22 does not determine the moving direction of the finger in the target switch, and does not increment both of the right counter R and the left counter L. Then, the determination unit 22 determines whether the process of S36 to S44 has been performed in all the switches SW1 to SW8 (S46). When the determination result of S46 is NO, a next switch is incremented and the procedure returns to S36. The subsequent processing is performed in the same manner as the above-mentioned processing.

When the determination result of S46 is YES, the determination unit 22 compares values of the right counter R and the left counter L, and determines whether the value of the right counter R is more than that of the left counter L (S48). When the determination result of S48 is YES, the determination unit 22 determines the rotational direction of the grip as the right direction (S50). In this case, the rotational input of the right rotation is performed. The determination unit 22 indicates the determined rotational direction to the indicator 24, and/or notifies the information processing terminal 30 of the determined rotational direction. Then, the procedure advances to S56, and the determination unit 22 stores the switch state of each switch acquired in S30 into the memory 26.

On the other hand, when the determination result of S48 is NO, the determination unit 22 compares the values of the right counter R and the left counter L, and determines whether the value of the left counter L is more than that of the right counter R (S52). When the determination result of S52 is YES, the determination unit 22 determines the rotational direction of the grip as the left direction (S54), indicates the determined rotational direction to the indicator 24, and/or notifies the information processing terminal 30 of the determined rotational direction. Then, the procedure advances to S56, and the determination unit 22 stores the switch state of each switch at that time into the memory 26.

When the determination result of S52 is NO, i.e., when the values of the right counter R and the left counter L are the same, the determination unit 22 cannot determine the rotational direction. At this time, the determination unit 22 stores the switch states acquired in S30 into the memory 26 as the previous switch states without determining the rotational direction (S56). Then, the procedure returns to S10.

Thus, in the first embodiment, the determination unit 22 determines the rotational direction of the grip based on a magnitude relationship of the values stored in the right counter R and the left counter L.

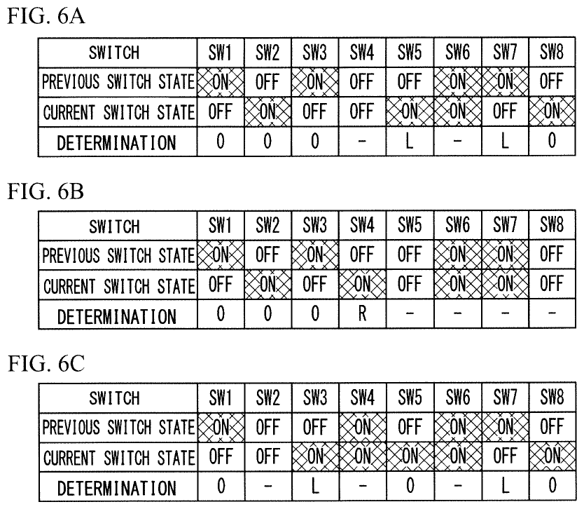

FIGS. 6A to 6C are views illustrating an example of the determination of the rotational direction. In FIG. 6A to 6C, a field “switch” corresponds to the switches SW1 to SW8 of FIG. 1. It is assumed that a relationship of the right and left of each switch in FIGS. 6A to 6C corresponds to the positional relationship of the right and left of each switch 14 in the projection 12, and the switch SW1 is arranged on the right side of the switch SW8. A field “previous switch state” indicates the switch state of each of the switches SW1 to SW8 stored into the memory 26 in S26 or S56. A field “current switch state” indicates the switch state of each of the switches SW1 to SW8 acquired from the switches 14 in S30. A field “determination” indicates the determination result of S36 to S42. A code “-” indicates that the determination result of S36 is NO, i.e., the current switch state of the target switch 14 is not changed from the previous switch state. A code “0” indicates that the determination result of S36 is YES and the determination results of S38 and S42 are NO, i.e., the moving direction of the finger is not determined. A code “R” indicates that the determination result of S38 is YES, i.e., it is determined that the finger has moved to the right. A code “L” indicates that the determination result of S42 is YES, i.e., it is determined that the finger has moved to the left.

FIG. 6A illustrates an example in which the current switch state is shifted to the left one by one from the previous switch state. In this case, the grip way of the projection 12 by the operator is not changed and the grip is moving to the left.

For the switch SW4, the determination result of S36 is NO and the “determination” in FIG. 6A is “-” since the previous switch state and the current switch state of the switch SW4 are OFF as illustrated in FIG. 6A. For the switch SW6, since the previous switch state and the current switch state are ON, the determination result of S36 is NO and the “determination” in FIG. 6A is “-”. The current switch states of the other switches are changed from the previous switch states thereof, and the determination result of S36 is YES.

The current switch state of the switch SW1 is OFF, and the previous switch states of the switches SW8 and SW2 on the both sides are OFF. Therefore, the determination results of S38 and S42 are NO, and the “determination” of the switch SW1 in FIG. 6A is “0”. Similarly, the “determination” of the switch SW3 in FIG. 6A is “0”. The current switch state of the switch SW2 is ON, and the previous switch states of the switches SW1 and SW3 on the both sides are ON. Therefore, the determination results of S38 and S42 are NO, and the “determination” of the switch SW2 in FIG. 6A is “0”. Similarly, the “determination” in FIG. 6A of the switch SW8 in FIG. 6A is “0”. In any of the switches SW1, SW2, SW3 and SW8, the moving direction of the grip is not determined.

For the switch SW5, the current switch state is ON, the previous switch states of the switch SW4 on the left side is OFF, and the previous switch states of the switch SW6 on the right side is ON. Therefore, only the previous switch state of the switch SW6 matches the current switch state of the switch SW5. Therefore, the determination result of S42 is YES, and the “determination” of the switch SW5 in FIG. 6A is “L”.

The current switch state of the switch SW7 is OFF, the previous switch states of the switch SW6 on the left side is ON, and the previous switch states of the switch SW8 on the right side is OFF. Therefore, the determination result of S42 is YES and the “determination” of the switch SW7 in FIG. 6A is “L”.

In an example of FIG. 6A, the number of “R” is 0 and the number of is 2. Therefore, the determination result of S48 is NO and the determination result of S52 is YES, and therefore the determination unit 22 determines the rotational direction of the grip as the left direction in S54. Thus, the determination unit 22 can determine the rotational direction of the grip of the projection 12 by the operator.

FIG. 6B illustrates an example in which the current switch states and the previous switch states of the switches SW5 to SW8 are the same as each other, and the current switch states of the switches SW1 to SW4 are shifted to the right one by one from the previous switch states. This corresponds to a case where some of the fingers of the operator which has gripped the projection 12 does not move, and some of the fingers is moving to the right, for example.

As illustrated in FIG. 6B, the current switch states and the previous switch states of the switches SW5 to SW8 are not changed. The determination result of S36 is NO, and the “determination” of the switches SW5 to SW8 in FIG. 6B is “-”. In each of the switches SW1 to SW3, the current switch state is the same as the previous switch states of the switches on the both sides. The determination results of S38 and S42 are NO, and the “determination” of the switches SW1 to SW3 in FIG. 6B is “0”.

The current switch state of the switch SW4 is ON, the previous switch state of the switch SW3 on the left side is ON, and the previous switch state of the switch SW5 on the left side is OFF. Therefore, only the previous switch state of the switch SW3 matches the current switch state of the switch SW4, the determination result of S38 is YES, and the “determination” of the switch SW4 in FIG. 6B is “R”.

In an example of FIG. 6B, the number of “R” is 1 and the number of “L” is 0. Therefore, the determination result of S48 is YES, and the determination unit 22 determines the rotational direction of the grip as the right direction in S50.

FIG. 6C illustrates an example in which the current switch state of each switch is basically shifted to the left one by one from the previous switch state, but the current switch state of the switch SW4 is reversed from the previous switch state of the switch SW5. This corresponds to a case where the number of fingers of the operator which has gripped the projection 12 is increased or decreased compared to the previous switch state, for example.

As illustrated in FIG. 6C, the current switch states and the previous switch states of the switches SW2, SW4 and SW6 are not changed. The determination result of S36 is NO, and the “determination” of the switches SW2, SW4 and SW6 in FIG. 6C is “-”. In each of the switches SW1, SW5 and SW8, the current switch state is the same as the previous switch states of the switches on the both sides. The determination results of S38 and S42 are NO, and the “determination” of the switches SW1, SW5 and SW8 in FIG. 6C is “0”.

The current switch state of each of the switches SW3 and SW7 matches only the previous switch state of the switch on the right side. The determination result of S42 is YES, and the “determination” of the switches SW3 and SW7 in FIG. 6C is “L”.

In an example of FIG. 6C, the number of “R” is 0 and the number of is 2. Therefore, the determination result of S52 is YES, and the determination unit 22 determines the rotational direction of the grip as the left direction in S54. Thus, the determination unit 22 can determine the rotational direction of the grip of the projection 12 by the operator.

Since the projection 12 is fixed to the substrate 18, when the operator rotates the fingers so as to trace the projection 12 while gripping the projection 12, the grip way is not always constant. When the operator rotates three fingers while pinching the projection 12 for example, the three fingers do not necessarily move in the same way. For example, there is a case where some of the fingers does not move, or a certain finger moves in the opposite direction of the other fingers. Moreover, there is a case where any of the fingers that has gripped the projection 12 is released from the projection 12, or a finger that is not gripping the projection 12 touches the projection 12. In such cases, the determination unit 22 is likely to erroneously determine the rotational direction of the grip by the operator.

For this reason, according to the first embodiment, the determination unit 22 acquires the current switch state of each of the switches 14, as illustrated in S30. As indicated by S36 to S54, the determination unit 22 determines the rotational direction of the grip based on the current switch states of the switches SW1 to SW8 acquired in S30 and the previous switch states of the switches SW1 to SW8 stored into the memory 26. Thus, the rotational direction is determined based on the previous switch state and the current switch state, so that the erroneous determination of the rotation direction can be suppressed.

As indicated by S38 to S44 and S48 to S54, the determination unit 22 determines the rotational direction of the grip based on a comparison between the current switch state of each of the switches SW1 to SW8 and the previous switch states of the switches arranged on the both sides of the target switch. Thus, the current switch state of the switch to be determined is compared with the previous switch states of the switches arranged on the both sides thereof, so that the erroneous determination of the rotation direction can be more suppressed.

As indicated by S42 and S44, the determination unit 22 calculates the number of switches L in which the current switch state matches only the previous switch state of the switch on the right side. Similarly, as indicated by S38 and S40, the determination unit 22 calculates the number of switches R in which the current switch state matches only the previous switch state of the switch on the left side. Then, as indicated by S48 to S54, the determination unit 22 determines the rotation direction based on the calculated numbers of switches R and L. Thus, the rotational direction is determined based on the calculated number of switches R and L, so that the erroneous determination of the rotation direction can be suppressed.

It is unclear whether the finger is rotated for the switch in which the current switch state and the previous switch state are the same, even when the current switch state of the switch matches the previous switch state of only one switch among the switches on both sides. Therefore, as indicated by S36, the determination unit 22 extracts any of the switches SW1 to SW8 in which the current switch state differs from the previous switch state. The determination unit 22 determines the rotational direction of the operation based on the switch state of the extracted switch. For example, the determination unit 22 compares the current switch state of the extracted switch with the previous switch states of the switches located on both side of the extracted switch, and determines the rotational direction based on the comparison. Thereby, the erroneous determination of the rotation direction can be more suppressed.

When the determination unit 22 determines the rotational direction of the grip based on the switch states of the switches 14, there is a possibility that the finger moves carelessly, and the erroneous determination may occur if the determination unit 22 tries to determine the rotation direction in a state where the grip is not determined.

Therefore, as indicated by S22, the determination unit 22 determines whether the switch states of all the switches 14 are not changed for the given time period. When the determination unit 22 determines that the switch states of all the switches 14 are not changed for the given time period, the determination unit 22 determines the rotational direction based on the switch states of the switches 14, as indicated by S12 and FIG. 5. Thus, the determination unit 22 starts the determination of the rotational direction when the grip way is not changed for the given time period, and the erroneous determination of the rotation direction can be suppressed.

When all the switches 14 are turned on or off as indicated by S34, the determination unit 22 determines that the operator has released the finger from the projection 12, and executes the processing of S32 and FIG. 4. That is, the determination unit 22 releases the state in which the grip way is decided, and determines again whether the switch state of the switches 14 is not changed for the given time period to suppress the erroneous determination of the rotation direction.

When only one finger touches the projection 12 for example, there is a possibility that the operator touches the projection 12 without the intention of operating the operation unit 10. Therefore, it is possible to control the determination unit 22 to receive the operation input from the operation unit 10 only when a plurality of fingers touch the projection 12.

Here, the “right” and the “left” in the embodiment is a term used to indicate the relative rotational direction as viewed in a state of FIG. 1A.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various change, substitutions, and alterations could be made hereto without departing from the spirit and scope of the invention.

What is claimed is:

1. A switch system comprising:
a projection;
a plurality of switches that are arranged on a side surface of the projection along a circumferential direction, each switch detecting touch to the side surface of the projection by an operator as on or off; and
a determiner that acquires on/off states of the switches, and determines a rotational direction of an operator's finger along the circumferential direction of the projection based on a current on/off state currently acquired from each switch and a previous on/off state previously acquired from each switch.

2. The switch system as claimed in claim 1, wherein
the determiner determines the rotational direction based on a comparison result of the current on/off state currently acquired from each switch and previous on/off states previously acquired from switches located on both sides of the each switch.

3. The switch system as claimed in claim 1, wherein
the determiner determines the rotational direction based on a number of switches in which the current on/off state currently acquired from each switch matches the previous on/off state previously acquired from a switch located on a right side of the each switch among switches located on both sides of the each switch, and a number of switches in which the current on/off state currently acquired from each switch matches the previous on/off state previously acquired from a switch located on a left side of the each switch among the switches located on both sides of the each switch.

4. The switch system as claimed in claim 1, wherein
the determiner extracts a switch in which the current switch state differs from the previous switch state, from the plurality of switches, and determines the rotational direction based on a number of switches in which the current on/off state of the extracted switch matches only the previous switch state of a switch located on a right side of the extracted switch, and a number of switches in which the current on/off state of the extracted switch matches only the previous switch state of a switch located on a left side of the extracted switch.

5. The switch system as claimed in claim 1, wherein
the determiner extracts a switch in which the current switch state differs from the previous switch state, from the plurality of switches, compares the current on/off state of the extracted switch with previous on/off states of switches located on both sides of the extracted switch, and determines the rotational direction based on a comparison result.

6. The switch system as claimed in claim 1, wherein
the determiner determiners the rotational direction after the determiner determiners that an on/off state of each of the switches is not changed for a given time period.

7. A switch system comprising:
a projection;
a plurality of switches that are arranged on a side surface of the projection along a circumferential direction, each switch detecting touch to the side surface of the projection by an operator as on or off; and
a determiner that determines whether an on/off state of each of the switches is not changed for a given time period, and determines a rotational direction of an operator's finger along the circumferential direction of the projection based on on/off states of the switches when it is determined that the on/off state of each of the switches is not changed for the given time period.
